(19) United States
(12) Patent Application Publication
(10) Pub. No.: US 2013/0057274 A1
(43) Pub. Date: Mar. 7, 2013

(54) CURRENT SENSOR

(71) Applicants: Yosuke IDE, Niigata-ken (JP); Yoshihiro NISHIYAMA, Niigata-ken (JP)

(72) Inventors: Yosuke IDE, Niigata-ken (JP); Yoshihiro NISHIYAMA, Niigata-ken (JP)

(73) Assignee: ALPS GREEN DEVICES CO., LTD., Tokyo (JP)

(21) Appl. No.: 13/587,786

(22) Filed: Aug. 16, 2012

(30) Foreign Application Priority Data
Sep. 6, 2011 (JP) 2011-193709

(51) Int. Cl. G01R 33/09

(52) U.S. Cl. 324/252

(57) ABSTRACT

A current sensor includes a magnetoresistance effect element in which a plurality of magnetic detecting portions and a plurality of permanent magnet portions are alternately arranged so as to be in contact with each other. Each magnetic detecting portion is configured to include a ferromagnetic fixed layer whose magnetization direction is substantially fixed and a free magnetic layer whose magnetization direction changes with respect to an external magnetic field. Each permanent magnet portion is configured to include a hard bias layer applying a bias magnetic field to the free magnetic layer. An interval between the adjacent permanent magnet portions is 20 μm to 100 μm.

### CLAIM OF PRIORITY

This application claims benefit of Japanese Patent Application No. 2011-193709 filed on Sep. 6, 2011, which is hereby incorporated by reference.

### BACKGROUND OF THE INVENTION

1. Field of the Invention

The present invention relates to a current sensor using a magnetoresistance effect element.

2. Description of the Related Art

In fields such as electric vehicle and solar cell, a current sensor is used which includes a magnetic detection element that detects and outputs an induced magnetic field from a current to be measured. Magnetic detecting elements for use in current sensors include magnetoresistance effect elements such as a GMR element.

A GMR element is composed of, for example, an antiferromagnetic layer, a ferromagnetic fixed layer, a nonmagnetic material layer, a free magnetic layer, and the like. In the GMR element, the ferromagnetic fixed layer is provided on the antiferromagnetic layer so as to be in contact therewith, and a magnetization direction thereof is fixed as one direction by an exchange coupling magnetic field generated between the ferromagnetic fixed layer and the antiferromagnetic layer. The free magnetic layer is laminated on the ferromagnetic fixed layer via the nonmagnetic material layer (nonmagnetic intermediate layer), and a magnetization direction thereof varies by an external magnetic field.

The electric resistance of the GMR element varies in accordance with the relationship between the magnetization direction of the free magnetic layer, which varies by application of an external magnetic field, and the magnetization direction of the ferromagnetic fixed layer. In a current sensor including such a GMR element, a current value of a current to be measured is calculated on the basis of an electric resistance value of the GMR element which varies by application of an induced magnetic field generated by the current to be measured. In the current sensor, use of a GMR element including a hard bias layer for applying a bias magnetic field to a free magnetic layer is proposed in order to suppress characteristic deterioration caused by magnetic hysteresis (e.g., see Japanese Unexamined Patent Application Publication No. 2006-66821).

In the GMR element disclosed in Japanese Unexamined Patent Application Publication No. 2006-66821, the magnetization direction of a free magnetic layer is initialized by a magnetic field being applied from a hard bias layer to a free magnetic layer, and thus magnetic hysteresis can be suppressed to some extent. However, in the GMR element described above, since the free magnetic layer is provided on the hard bias layer so as to be in contact therewith, the magnetization direction of the free magnetic layer is strongly fixed at a contact potion between the free magnetic layer and the hard bias layer by the bias magnetic field of the hard bias layer. As a result, even when the induced magnetic field from the current to be measured acts, the magnetization direction at the contact portion does not change, resulting in decrease in the detection sensitivity and the linearity of output of the current sensor. In addition, magnetic hysteresis cannot be sufficiently suppressed.

The present invention has been made in view of such a point and provides a current sensor having low magnetic hysteresis, high linearity, and high detection sensitivity.

### SUMMARY OF THE INVENTION

According to the present invention, a current sensor includes: a magnetoresistance effect element in which a plurality of magnetic detecting portions and a plurality of permanent magnet portions are alternately arranged so as to be in contact with each other, each magnetic detecting portion being configured to include a ferromagnetic fixed layer whose magnetization direction is substantially fixed and a free magnetic layer whose magnetization direction changes with respect to an external magnetic field, each permanent magnet portion being configured to include a hard bias layer applying a bias magnetic field to the free magnetic layer. An interval between the adjacent permanent magnet portions is 20 μm to 100 μm.

According to this configuration, since each permanent magnet portion is provided between the adjacent magnetic detecting portions in the magnetoresistance effect element, the area of a contact portion between the free magnetic layer and the hard bias layer is not increased, and an insensible region of the free magnetic layer can be sufficiently decreased. In addition, since the interval between the adjacent permanent magnet portions is set to 20 μm to 100 μm, a current sensor having low magnetic hysteresis, high linearity, and high detection sensitivity can be realized.

In the current sensor according to the present invention, a width of each magnetic detecting portion is preferably 0.5 μm to 1.5 μm. According to this configuration, a current sensor can be realized in which low magnetic hysteresis, high linearity, and high detection sensitivity are well balanced.

In the current sensor according to the present invention, a magnetization amount of each free magnetic layer is preferably 0.6 memu/cm2 to 1.0 memu/cm2. According to this configuration, a current sensor can be realized in which low magnetic hysteresis, high linearity, and high detection sensitivity are well balanced.

In the current sensor according to the present invention, each permanent magnet portion is preferably configured to include an electrically conductive layer connecting electrically the magnetic detecting portions adjacent thereto. According to this configuration, since the adjacent magnetic detecting portions are electrically connected to each other by the electrically conductive layer, increase, variation, or the like of the electric resistance by each permanent magnet portion can be suppressed. Thus, a current sensor having high measurement accuracy can be realized.

The current sensor according to the present invention is preferably a magnetic proportional current sensor configured to include the magnetoresistance effect element and including a bridge circuit for detecting a magnetic field, the bridge circuit including two outputs generating a voltage difference substantially proportional to an induced magnetic field. In a magnetic proportional current sensor which does not include control means such as a feedback coil, the characteristics of the magnetoresistance effect element are directly linked to the characteristics of the current sensor. Thus, because of the above configuration, the characteristics of the current sensor can be remarkably enhanced.

### BRIEF DESCRIPTION OF THE DRAWINGS

FIG. 1 is a schematic diagram of a current sensor according to an embodiment;

FIG. 2 is a schematic plan view of the current sensor according to the embodiment;

FIG. 3 is a schematic plan view of a magnetoresistance effect element used in the current sensor according to the embodiment;

FIG. 4 is a schematic cross-sectional view showing a lamination structure of the magnetoresistance effect element used in the current sensor according to the embodiment;

FIG. 5 is a characteristic diagram showing the relationship between magnetic hysteresis and the interval between adjacent permanent magnet portions in the magnetoresistance effect element;

FIG. 6 is a characteristic diagram showing the relationship between nonlinearity and the interval between the adjacent permanent magnet portions in the magnetoresistance effect element;

FIG. 7 is a characteristic diagram showing the relationship between sensitivity of the current sensor and the interval between the adjacent permanent magnet portions in the magnetoresistance effect element;

FIG. 8 is a characteristic diagram showing the relationship between magnetic hysteresis and the width of a magnetic detecting portion in the magnetoresistance effect element;

FIG. 9 is a characteristic diagram showing the relationship between nonlinearity and the width of the magnetic detecting portion in the magnetoresistance effect element;

FIG. 10 is a characteristic diagram showing the relationship between sensitivity of the current sensor and the width of the magnetic detecting portion in the magnetoresistance effect element;

FIG. 11 is a characteristic diagram showing the relationship between magnetic hysteresis and a magnetization amount of a free magnetic layer in the magnetoresistance effect element;

FIG. 12 is a characteristic diagram showing the relationship between nonlinearity and the magnetization amount of the free magnetic layer in the magnetoresistance effect element; and

FIG. 13 is a characteristic diagram showing the relationship between sensitivity of the current sensor and the magnetization amount of the free magnetic layer in the magnetoresistance effect element.

### DESCRIPTION OF THE PREFERRED EMBODIMENTS

In a current sensor including a magnetoresistance effect element, it is made possible to reduce magnetic hysteresis by providing a hard bias layer to provide uniaxial anisotropy to a free magnetic layer. However, various characteristics of the current sensor may deteriorate when the hard bias layer and the free magnetic layer are merely disposed.

The inventors of the present invention confirmed that characteristic deterioration of the above current sensor occurs due to the interval between hard bias layers and found that characteristics of the current sensor such as magnetic hysteresis, linearity, and detection sensitivity largely depend on the interval between hard bias layers each provided by removing a portion of a magnetic detecting pattern. Then, the inventors found that when the interval between adjacent hard bias layers is set to 20 μm to 100 μm, a current sensor can be implemented which has low magnetic hysteresis, high linearity, and high detection sensitivity, and completed the present invention.

In other words, an essential feature of the present invention is that magnetic detecting portions each including a free magnetic layer and permanent magnet portions each including a hard bias layer are alternately arranged to form a magnetic detection pattern and the interval between the adjacent permanent magnet portions is set to 20 μm to 100 μm. Hereinafter, an embodiment of the present invention will be described in detail with reference to the accompanying drawings.

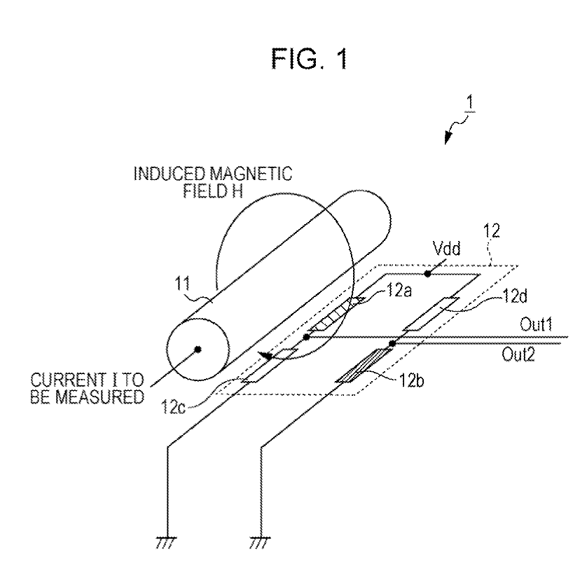

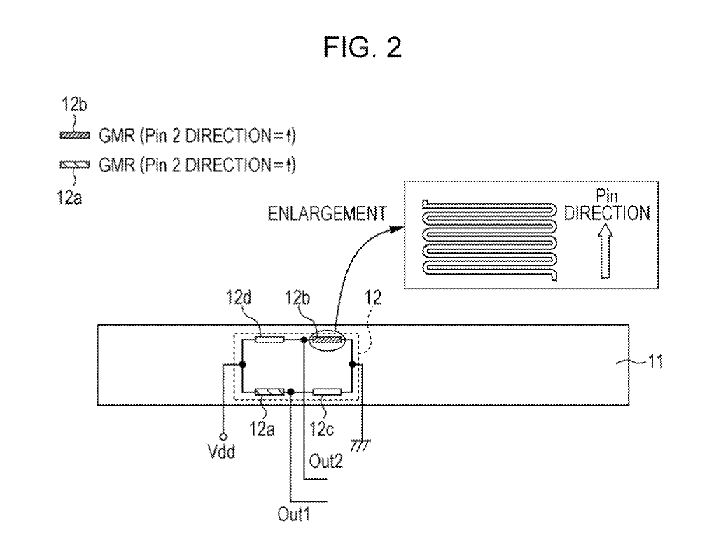

FIGS. 1 and 2 are schematic diagrams showing an example of a current sensor according to the embodiment of the present invention. The current sensor 1 shown in FIGS. 1 and 2 is a magnetic proportional current sensor and is provided adjacent to a conductor 11 through which a current Ito be measured flows. The magnetic proportional current sensor 1 will be described below in which the advantageous effects of the present invention significantly appear, but an object to which the present invention is applied is not limited thereto. For example, the present invention may be applied to a magnetic balance current sensor in which a cancel magnetic field for cancelling an induced magnetic field is generated by a feedback coil and the magnitude of a current to be measured is calculated from a current flowing through the feedback coil.

The current sensor 1 shown in FIGS. 1 and 2 has a magnetic field detection bridge circuit 12 which detects an induced magnetic field H generated by the current Ito be measured, which flows through the conductor 11. The magnetic field detection bridge circuit 12 is composed of: two magnetoresistance effect elements 12a and 12b whose resistance values change by application of the induced magnetic field H from the current I to be measured; and two fixed resistance elements 12c and 12d whose resistance values do not change by the induced magnetic field H. When the magnetic field detection bridge circuit 12 having magnetoresistance effect elements is used as described above, a high-sensitivity current sensor 1 can be realized. It is noted that the magnetic field detection bridge circuit 12 is not limited to a full-bridge circuit composed of four elements and may be a half-bridge circuit composed of two elements. In addition, the number of the magnetoresistance effect elements used in the magnetic field detection bridge circuit 12 can be changed as appropriate. For example, the magnetic field detection bridge circuit 12 may be configured by using four magnetoresistance effect elements.

The magnetic field detection bridge circuit 12 includes two outputs Out1 and Out2 that generate a voltage difference corresponding to the induced magnetic field H generated by the current Ito be measured. As shown in FIG. 2, in the magnetic field detection bridge circuit 12, a power source Vdd is connected to a connection point between the magnetoresistance effect element 12a and the fixed resistance element 12d, and a ground GND is connected to a connection point between the magnetoresistance effect element 12b and the fixed resistance element 12c. The output Out1 is connected to a connection point between the magnetoresistance effect element 12a and the fixed resistance element 12c, and the output Out2 is connected to a connection point between the magnetoresistance effect element 12b and the fixed resistance element 12d. The current sensor 1 calculates a current value of the current Ito be measured, on the basis of the voltage difference between the output Out1 and the output Out2.

As shown in an enlarged view of FIG. 2, the magnetoresistance effect elements 12a and 12b are each composed of a meander-shaped magnetic detection pattern including a plurality of elongated patterns that are arranged substantially parallel to each other. The sensitivity axis directions of the magnetoresistance effect elements 12a and 12b are directions substantially orthogonal to the longitudinal directions of the elongated patterns. Thus, the magnetoresistance effect elements 12a and 12b are arranged such that the direction of the induced magnetic field H generated by the current Ito be measured is substantially orthogonal to the longitudinal directions of the elongated patterns. As the magnetoresistance effect elements 12a and 12b, GMR (Giant Magnet Resistance) elements are used in the present embodiment. However, TMR (Tunnel Magnet Resistance) elements or the like may be used.

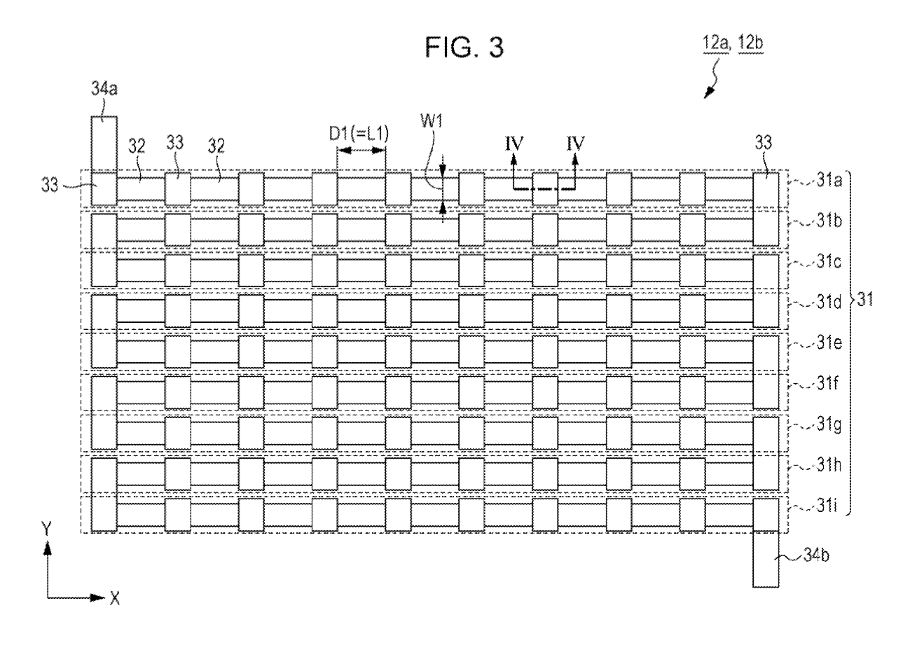

FIG. 3 is a schematic plan view showing the configuration of the magnetoresistance effect element 12a or 12b used in the current sensor 1 according to the present embodiment. As shown in FIG. 3, in the magnetoresistance effect element 12a or 12b, a plurality of elongated patterns 31 whose planar shapes are substantially rectangular are arranged at a predetermined interval along a direction (Y direction) orthogonal to the longitudinal direction (X direction) of the elongated patterns 31, such that the elongated patterns 31 are substantially parallel to each other. FIG. 3 shows a magnetic detection pattern including nine elongated patterns 31a to 31i, but the number of the elongated patterns 31 is not limited thereto.

Each elongated pattern 31 is configured to include a plurality of magnetic detecting portions 32 and a plurality of permanent magnet portions 33. The magnetic detecting portions 32 are arranged so as to be spaced apart from each other at a predetermined interval in the longitudinal direction of the elongated pattern 31. In addition, one permanent magnet portion 33 is provided between two adjacent magnetic detecting portions 32. In other words, each elongated pattern 31 is configured such that the magnetic detecting portions 32 and the permanent magnet portions 33 are alternately connected to each other.

The permanent magnet portion 33 on one end side (the left-side end portion shown in FIG. 3) of the elongated pattern 31a that is provided on the outermost side in the arrangement direction of the elongated patterns 31 (the Y direction) is connected to a connection terminal 34a. Meanwhile, the permanent magnet portion 33 on another end portion (the left-side end portion shown in FIG. 3) of the elongated pattern 31i that is provided so as to be most distant from the elongated pattern 31a in the arrangement direction of the elongated pattern 31a is connected to a connection terminal 34b.

Another end portion of the elongated pattern 31a and another end portion of the elongated pattern 31b adjacent to the elongated pattern 31a are connected to each other by the permanent magnet portion 33, and one end portion of the elongated pattern 31b and one end portion of the elongated pattern 31c adjacent to the elongated pattern 31b are connected to each other by the permanent magnet portion 33. Similarly, another end portion of the elongated pattern 31c and another end portion of the adjacent elongated pattern 31d are connected to each other by the permanent magnet portion 33, and one end portion of the elongated pattern 31d and one end portion of the adjacent elongated pattern 31e are connected to each other by the permanent magnet portion 33. Furthermore, another end portion of the elongated pattern 31e and another end portion of the adjacent elongated pattern 31f are connected to each other by the permanent magnet portion 33, and one end portion of the elongated pattern 31f and one end portion of the adjacent elongated pattern 31g are connected to each other by the permanent magnet portion 33. Another end portion of the elongated pattern 31g and another end portion of the adjacent elongated pattern 31h are connected to each other by the permanent magnet portion 33, and one end portion of the elongated pattern 31h and one end portion of the adjacent elongated pattern 31i are connected to each other by the permanent magnet portion 33. In this manner, each of the permanent magnet portions 33 at both end portions of each elongated pattern 31 other than the permanent magnet portions 33 that are connected to the connection terminals 34a and 34b, respectively, forms a bending portion that connects the adjacent elongated patterns 31 to each other, whereby a meander-shaped magnetic detection pattern is formed. It is noted that as compared to the shapes of the permanent magnet portions 33 that are connected to the connection terminals 34a and 34b, respectively, the shapes of the other permanent magnet portions 33 are formed so as to extend in the arrangement direction of the elongated patterns 31 such that the elongated patterns 31 are commonly connectable to each other.

When a current flows from the power source Vdd to the ground GND through the connection terminals 34a and 34b of each of the magnetoresistance effect elements 12a and 12b, a voltage drop occurs in accordance with an electric resistance value of the meander-shaped magnetic detection pattern. The electric resistance value of the meander-shaped magnetic detection pattern varies by the induced magnetic field H generated by the current Ito be measured, and thus the voltage drop also varies in accordance with the magnitude of the induced magnetic field H. Since one of the connection terminals 34a and 34b is connected to one of the outputs Out1 and Out2, a voltage value corresponding to the voltage drop generated in the meander-shaped magnetic detection pattern, namely, a voltage value corresponding to the magnitude of the induced magnetic field H, is provided to the output Out1 or the output Out2. The outputs Out1 and Out2 are connected to a calculation section which is not shown, and it is possible to calculate the current Ito be measured, from the voltage difference between the outputs Out1 and Out2.

In each elongated pattern 31 described above, the permanent magnet portions 33 are arranged at an interval D1. In other words, the plurality of magnetic detecting portions 32 are each formed so as to have a length L1 (a size in the X direction) equal to the interval D1. The interval D1 is specifically 20 μm to 100 μm. By so forming, the magnetic hysteresis of the current sensor 1 can be reduced so as to be low, the linearity thereof can be increased, and the detection sensitivity thereof can be increased.

In addition, in each elongated pattern 31, the plurality of magnetic detecting portions 32 are each formed so as to have a width W1 (a size in the Y direction). The width W1 is specifically 0.5 μm to 1.5 μm. By so forming, the magnetic hysteresis, the linearity, and the detection sensitivity of the current sensor 1 can be well balanced.

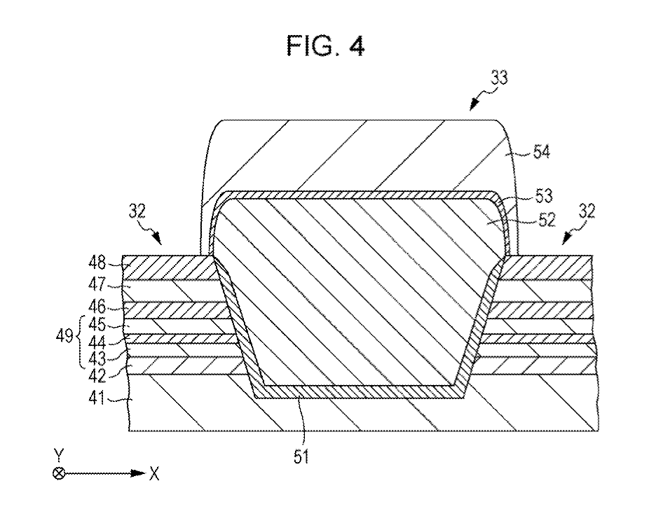

FIG. 4 is a schematic cross-sectional view showing a lamination structure of the magnetoresistance effect element 12a or 12b used in the current sensor 1 according to the present embodiment. FIG. 4 shows a cross section corresponding to a cross section taken along the A-A line in FIG. 3. As shown in FIG. 4, the magnetic detecting portions 32 and the permanent magnet portions 33 are provided on an aluminum oxide film 41 formed on a substrate such as a silicon substrate which is not shown. The aluminum oxide film 41 can be formed by, for example, a sputtering method or the like. Each magnetic detecting portion 32 is provided at a predetermined interval so as to be spaced apart from each other, and the permanent magnet portion 33 is provided between each magnetic detecting portion 32.

Each magnetic detecting portion 32 is formed by laminating a seed layer 42, a first ferromagnetic film 43, an antiparallel coupling film 44, a second ferromagnetic film 45, a nonmagnetic intermediate layer 46, a free magnetic layer 47, and a protective layer 48 in order. In each magnetic detecting portion 32, the first ferromagnetic film 43 and the second ferromagnetic film 45 are antiferromagnetically coupled to each other via the antiparallel coupling film 44, whereby a so-called self-pinned type ferromagnetic fixed layer (SFP layer: Synthetic Ferri Pinned layer) 49 is formed. As described above, the magnetoresistance effect elements 12a and 12b are each a spin valve type element using the ferromagnetic fixed layer 49, the nonmagnetic intermediate layer 46, and the free magnetic layer 47.

The seed layer 42 is formed from NiFeCr, Cr, or the like. It is noted that a base layer which is formed from, for example, a nonmagnetic material containing at least one element among Ta, Hf, Nb, Zr, Ti, Mo, and W may be provided between the seed layer 42 and the substrate which is not shown.

The first ferromagnetic film 43 is preferably formed from a CoFe alloy containing 40 atomic percent to 80 atomic percent of Fe. This is because the CoFe alloy of the composition range has a high coercive force and can stably maintain the magnetization with respect to an external magnetic field. It is noted that by applying a magnetic field in the widthwise direction of the elongated patterns 31 (the Y direction, see FIG. 3) during film formation, induced magnetic anisotropy is provided to the first ferromagnetic film 43. The direction of the applied magnetic field is, for example, a direction from the far side toward the near side of the surface of the sheet.

The antiparallel coupling film 44 is formed from Ru or the like. It is noted that the antiparallel coupling film 44 is desirably formed so as to have a thickness of 0.3 nm to 0.45 nm or of 0.75 nm to 0.95 nm. When the antiparallel coupling film 44 is formed so as to have such a thickness, strong antiferromagnetic coupling can be provided between the first ferromagnetic film 43 and the second ferromagnetic film 45.

The second ferromagnetic film 45 is preferably formed from a CoFe alloy containing 0 atomic percent to 40 atomic percent of Fe. This is because the CoFe alloy of the composition range has a low coercive force and is easily magnetized in an antiparallel direction (180° different direction) with respect to a preferential magnetization direction of the first ferromagnetic film 43a. It is noted that by applying, during film formation, a magnetic field that is the same as that during formation of the first ferromagnetic film 43 (a magnetic field in the widthwise direction of the elongated patterns 31, for example, a magnetic field in a direction from the far side toward the near side of the surface of the sheet), induced magnetic anisotropy is provided to the second ferromagnetic film 45. When film formation is conducted with application of such a magnetic field, the first ferromagnetic film 43 is preferentially magnetized in the direction of the applied magnetic field, and the second ferromagnetic film 45 is magnetized in the antiparallel direction (180° different direction) with respect to the magnetization direction of the first ferromagnetic film 43.

The nonmagnetic intermediate layer 46 is formed from Cu or the like. The composition of the nonmagnetic intermediate layer 46 can be changed as appropriate such that a desired characteristic is obtained.

The free magnetic layer 47 is formed from a magnetic material such as a CoFe alloy, a NiFe alloy, and a CoFeNi alloy. It is desirable that by applying a magnetic field in the lengthwise direction of the elongated patterns 31 (the X direction, see FIG. 3) during film formation, induced magnetic anisotropy is provided to the free magnetic layer 47. Because of this, magnetoresistance effect elements 12a and 12b can be realized whose resistances linearly change with respect to an external magnetic field in a stripe widthwise direction and which have low magnetic hysteresis. In addition, the free magnetic layer 47 is formed such that a magnetization amount thereof is 0.6 memu/cm2 to 1.0 memu/cm2 by the thickness of the free magnetic layer and selection of the magnetic material constituting the free magnetic layer 47. By so forming, the magnetic hysteresis, the linearity, and the detection sensitivity of the current sensor 1 can be well balanced.

The protective layer 48 is formed from Ta or the like. The composition of the protective layer 48 can be changed as appropriate such that a desired characteristic is obtained.

It is noted that it is preferable that in each magnetic detecting portion 32, the magnetization amount (Ms•t) of the first ferromagnetic film 43 and the magnetization amount (Ms•t) of the second ferromagnetic film 45 are substantially the same. When the difference in magnetization amount between the first ferromagnetic film 43 and the second ferromagnetic film 45 is substantially zero, an effective anisotropic magnetic field of the ferromagnetic fixed layer 49 is increased. Because of this, the stability of the magnetization of the ferromagnetic fixed layer 49 can be sufficiently ensured even without using an antiferromagnetic material. In addition, it is desirable that the Curie temperature (Tc) of the first ferromagnetic film 43 and the Curie temperature (Tc) of the second ferromagnetic film 45 are substantially the same. Because of this, the difference in magnetization amount (Ms•t) between the first ferromagnetic film 43 and the second ferromagnetic film 45 is substantially zero even in a high-temperature environment, and high magnetization stability can be maintained.

Each permanent magnet portion 33 is provided in a region where a portion of the magnetic detecting portion 32 provided on the aluminum oxide film 41 is removed by etching. Each permanent magnet portion 33 is configured to include a base layer 51 provided so as to cover the surface of the aluminum oxide film 41 and the side surfaces of the magnetic detecting portions 32, a hard bias layer 52 provided on the base layer 51, an anti-diffusion layer 53 provided on the hard bias layer 52, and an electrically conductive layer 54 provided on the anti-diffusion layer 53.

The base layer 51 is formed from Ta, a CrTi alloy, or the like. The base layer 51 is provided between the hard bias layer 52 and the free magnetic layers 47 of the magnetic detecting portions 32 and appropriately reduces a bias magnetic field applied to the free magnetic layers 47 of the magnetic detecting portions 32. When such a base layer 51 is provided, the hard bias layer 52 and the free magnetic layers 47 do not contact each other and thus fixation of the magnetization directions of the free magnetic layers 47 is suppressed. Because of this, insensible regions of the free magnetic layers 47 can be made sufficiently small and the magnetic hysteresis can be reduced.

The hard bias layer 52 is formed from a CoPt alloy, a CoCrPt alloy, or the like such that a bias magnetic field can be applied to the free magnetic layers 47 of the magnetic detecting portions 32. The hard bias layer 52 is provided such that the lower surface thereof is located below the lower surfaces of the seed layers 42 and the upper surface thereof is located above the upper surfaces of the protective layers 48, and the side surface regions of the free magnetic layers 47 are covered with the hard bias layer 52. By so forming, a bias magnetic field can be applied from a direction substantially orthogonal to the sensitivity axis direction of the free magnetic layers 47, and thus the magnetic hysteresis can be more effectively reduced.

The anti-diffusion layer 53 is provided so as to cover the hard bias layer 52. The anti-diffusion layer 53 is formed from Ta or the like.

The electrically conductive layer 54 is formed from Au, Al, Cu, Cr, Ta, or the like. The electrically conductive layer 54 is provided so as to cover the anti-diffusion layer 53. In addition, the electrically conductive layer 54 is provided so as to be in contact with the protective layers 48 of the magnetic detecting portions 32 in the longitudinal direction of the elongated patterns 31 (the X direction) and electrically connects the two magnetic detecting portions 32 that are spaced apart from each other by sandwiching the permanent magnet portion 33 therebetween. By so forming, the influence of a parasitic resistance by the hard bias layer 52 of the permanent magnet portion 33 is reduced and increase of the electric resistance value and variation of the electric resistance can be suppressed. As a result, high measurement accuracy can be achieved.

As described above, in the magnetoresistance effect elements 12a and 12b used in the current sensor 1 according to the present embodiment, when the interval D1 between the adjacent permanent magnet portions 33 is set to 20 μm to 100 μm, a current sensor having low magnetic hysteresis, high linearity, and high detection sensitivity can be realized.

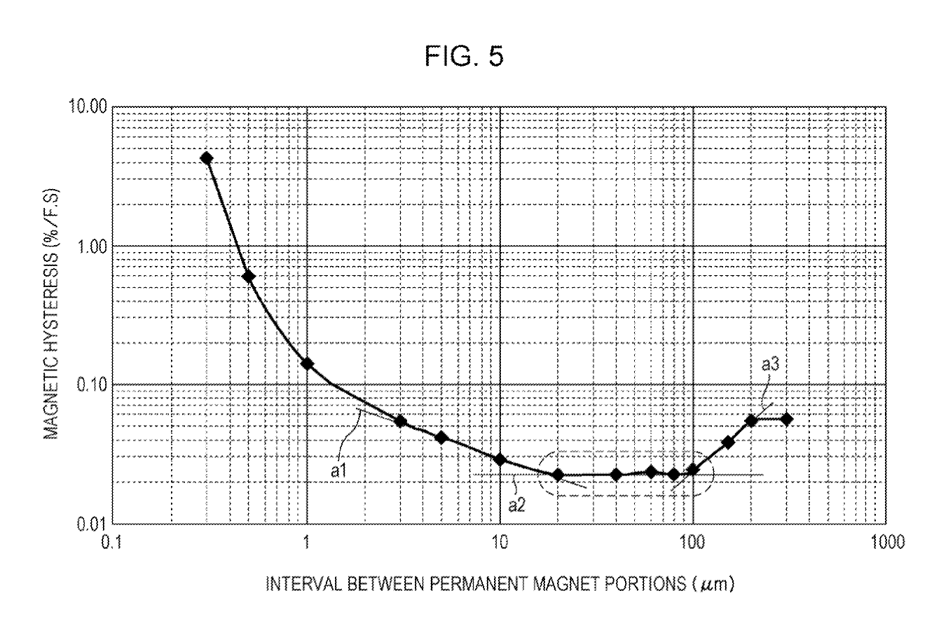

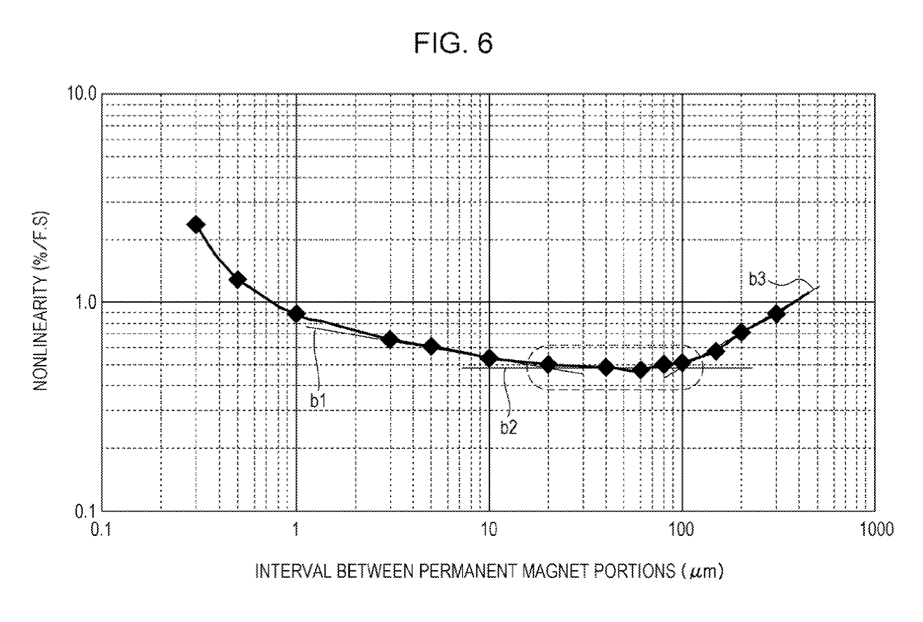

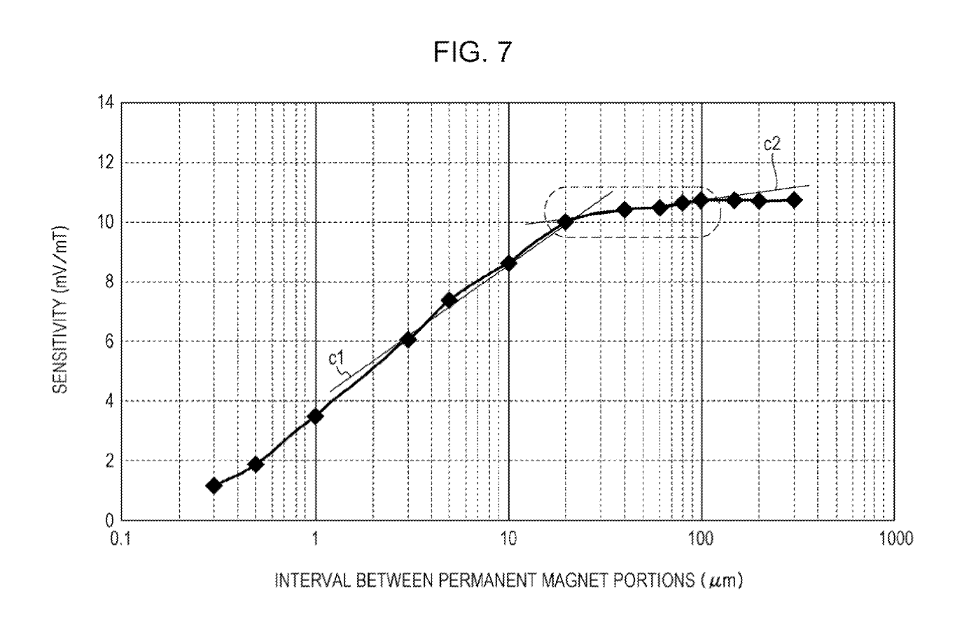

FIG. 5 is a characteristic diagram showing the relationship between magnetic hysteresis and the interval D1 between the adjacent permanent magnet portions 22 in the magnetoresistance effect element 12a or 12b. FIG. 6 is a characteristic diagram showing the relationship between nonlinearity and the interval D1 between the adjacent permanent magnet portions 33 in the magnetoresistance effect element 12a or 12b. FIG. 7 is a characteristic diagram showing the relationship between sensitivity of the current sensor and the interval D1 between the adjacent permanent magnet portions 33 in the magnetoresistance effect element 12a or 12b. For measurement of the characteristics in FIGS. 5 to 7, a magnetoresistance effect element is used which is composed of: magnetic detecting portions 32 each having a lamination structure of NiFeCr (seed layer: 4.2 nm)/Fe60Co40 (first ferromagnetic film: 1.9 nm)/Ru (antiparallel coupling film: 0.4 nm)/Co90Fe10 (second ferromagnetic film: 2.4 nm)/Cu (nonmagnetic intermediate layer: 2.2 nm)/Co90Fe10 (free magnetic layer: 1 nm)/Ni81.5Fe18.5 (free magnetic layer: 7 nm)/Ta (protective layer: 10 nm); and permanent magnet portions 33 each having a lamination structure of Ta (base layer: 1.5 nm)/CrTi (base layer: 3.5 nm)/CoPt (hard bias layer: 60 nm)/Ta (anti-diffusion layer: 5 nm)/Au (electrically conductive layer: 120 nm)/Ta (electrically conductive layer: 5 nm). The width W1 of each magnetic detecting portion 32 is fixed to 0.8 μm, and the magnetization amount of each free magnetic layer is fixed to 0.68 memu/cm2.

The magnetic hysteresis in FIG. 5 is calculated with definition of R0−+R0+/ΔRA×100(%) where a zero magnetic field resistance value after application of −40 mT is R0−, a zero magnetic field resistance value after application of +40 mT is R0+, and the difference between the resistance value at application of −40 mT and the resistance value at application of +40 mT is ARA. In addition, the nonlinearity in FIG. 6 is calculated on the basis of (ΔRinc/ΔRB+ΔRdec/ΔRB)/2×100(%) where the difference in maximum resistance value between a R−H curve and its linear regression straight line in the case where an applied magnetic field is increased from −4 mT to +4 mT is ΔRinc, the difference in maximum resistance value between a R−H curve and its linear regression straight line in the case where an applied magnetic field is decreased from +4 mT to −4 mT is ΔRdec, and the difference between the resistance value at application of −4 mT and the resistance value at application of +4 mT is ΔRB. Furthermore, the sensitivity of the current sensor in FIG. 7 is calculated with definition of (R+1−R−1)/R/20 where the average of the resistance value at +1 mT after application of −40 mT and the resistance value at +1 mT after application of +40 mT is R+1, the average of the resistance value at −1 mT after application of −40 mT and the resistance value at −1 mT after application of +40 mT is R−1, and the average of the above R0− and R0+ is R0.

In the characteristic diagram of FIG. 5, the gradient of the characteristic diagram (the gradient of approximate straight lines a1, a2, and a3) changes at the point where the interval D1 between the permanent magnet portions 33 is 20 μm and at the point where the interval D1 between the permanent magnet portions 33 is 100 μm. From FIG. 5, it appears that the magnetic hysteresis is sufficiently low in the range of 20 μm to 100 μm in which the approximate straight line a2 and the characteristic curve substantially coincide with each other. Similarly, in the characteristic diagram of FIG. 6, the gradient of the characteristic diagram (the gradient of approximate straight lines b1, b2, and b3) changes at the point where the interval D1 between the permanent magnet portions 33 is 20 μm and at the point where the interval D1 between the permanent magnet portions 33 is 100 μm. From FIG. 6, it appears that the nonlinearity is sufficiently low in the range of 20 μm to 100 μm in which the approximate straight line b2 and the characteristic curve substantially coincide with each other. This means that the linearity is sufficiently high in the range of 20 μm to 100 μm. Similarly, in the characteristic diagram of FIG. 7, the gradient of the characteristic diagram (the gradient of approximate straight lines c1 and c2) changes at the point where the interval D1 between the permanent magnet portions 33 is 20 μm. From FIG. 7, it appears that the sensitivity is sufficiently high in the range of 20 μm or larger in which the approximate straight line c2 and the characteristic curve substantially coincide with each other.

As described above, when the interval D1 between the permanent magnet portions 33 is set to 20 μm to 100 μm, a current sensor having low magnetic hysteresis, high linearity, and high detection sensitivity can be realized.

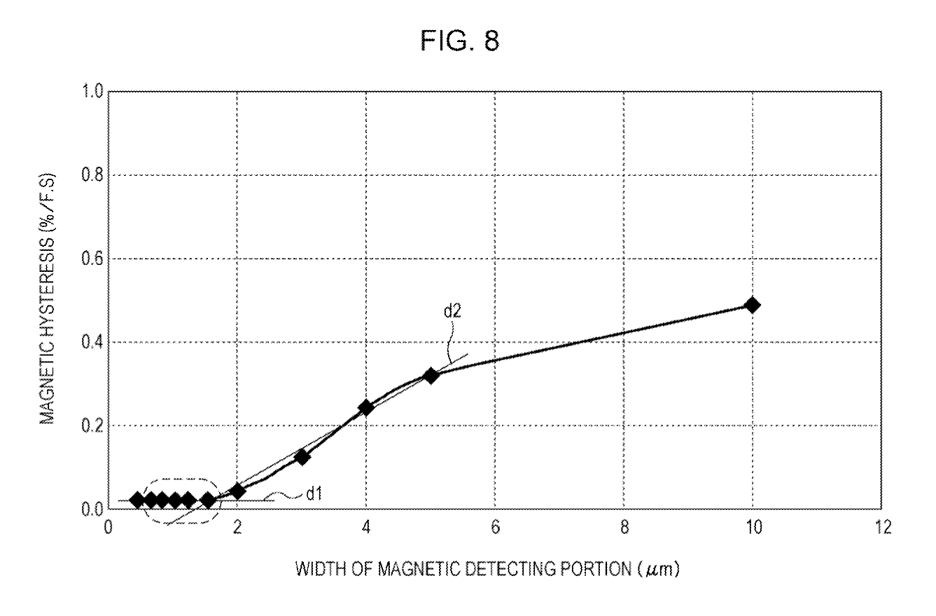

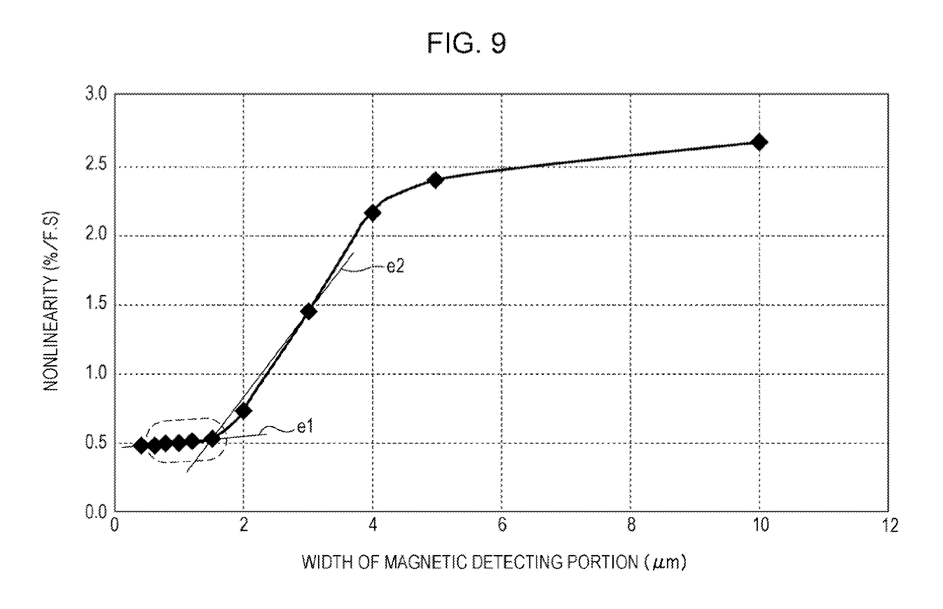

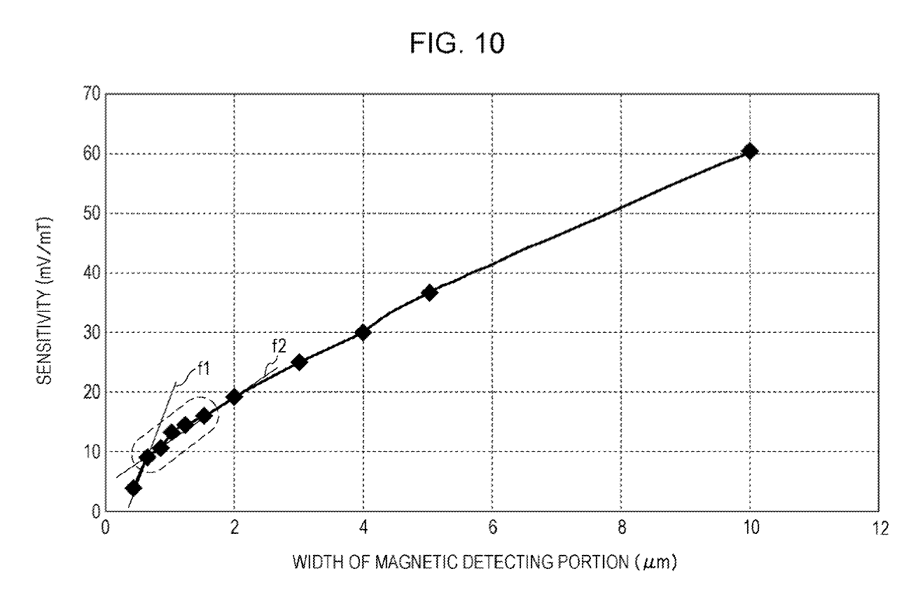

FIG. 8 is a characteristic diagram showing the relationship between magnetic hysteresis and the width W1 of the magnetic detecting portion 32 in the magnetoresistance effect element. FIG. 9 is a characteristic diagram showing the relationship between nonlinearity and the width W1 of the magnetic detecting portion 32 in the magnetoresistance effect element. FIG. 10 is a characteristic diagram showing the relationship between the sensitivity of the current sensor and the width W1 of the magnetic detecting portion 32 in the magnetoresistance effect element. For measurement of the characteristics in FIGS. 8 to 10, a magnetoresistance effect element is used which is composed of: magnetic detecting portions 32 each having a lamination structure of NiFeCr (seed layer: 4.2 nm)/Fe60Co40 (first ferromagnetic film: 1.9 nm)/Ru (antiparallel coupling film: 0.4 nm)/Co90Fe10 (second ferromagnetic film: 2.4 nm)/Cu (nonmagnetic intermediate layer: 2.2 nm)/Co90Fe10 (free magnetic layer: 1 nm)/Ni81.5Fe18.5 (free magnetic layer: 7 nm)/Ta (protective layer: 10 nm); and permanent magnet portions 33 each having a lamination structure of Ta (base layer: 1.5 nm)/CrTi (base layer: 3.5 nm)/CoPt (hard bias layer: 60 nm)/Ta (anti-diffusion layer: 5 nm)/Au (electrically conductive layer: 120 nm)/Ta (electrically conductive layer: 5 nm). The interval D1 between the adjacent permanent magnet portions 33 is fixed to 60 μm, and the magnetization amount of each free magnetic layer is fixed to 0.68 memu/cm2. The method for calculating each characteristic is the same as that in the case of FIGS. 5 to 7.

In the characteristic diagram of FIG. 8, the gradient of the characteristic diagram (the gradient of approximate straight lines d1 and d2) changes at the point where the width W1 of the magnetic detecting portion 32 is 1.5 μm. From FIG. 8, it appears that the magnetic hysteresis is sufficiently low in the range of 1.5 μm or less in which the approximate straight line d1 and the characteristic curve substantially coincide with each other. Similarly, in the characteristic diagram of FIG. 9, the gradient of the characteristic diagram (the gradient of approximate straight lines e1 and e2) changes at the point where the width W1 of the magnetic detecting portion 32 is 1.5 μm. From FIG. 9, it appears that the nonlinearity is sufficiently low in the range of 1.5 μm or less in which the approximate straight line e1 and the characteristic curve substantially coincide with each other. This means that the linearity is sufficiently high in the range of 1.5 μm or less. In addition, in the characteristic diagram of FIG. 10, the gradient of the characteristic diagram (the gradient of approximate straight lines f1 and f2) changes at the point where the width W1 of the magnetic detecting portion 32 is 0.6 μm. From FIG. 10, it appears that the sensitivity is high in the range of 0.6 μm or larger in which the approximate straight line f2 and the characteristic curve substantially coincide with each other.

As described above, when the width W1 of the magnetic detecting portion 32 is set to 0.6 μm to 1.5 μm, a current sensor can be realized in which low magnetic hysteresis, high linearity, and high detection sensitivity are well balanced.

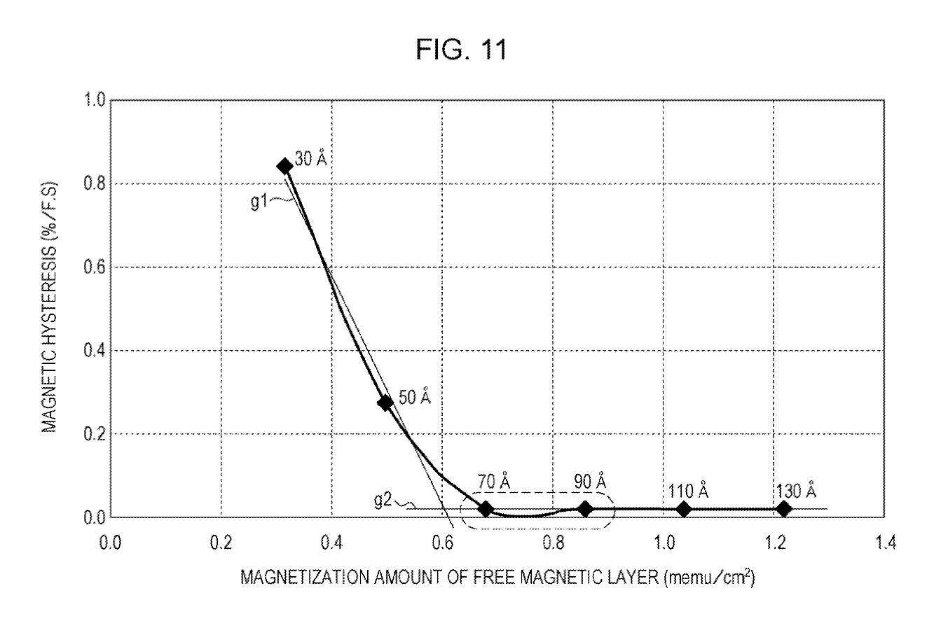

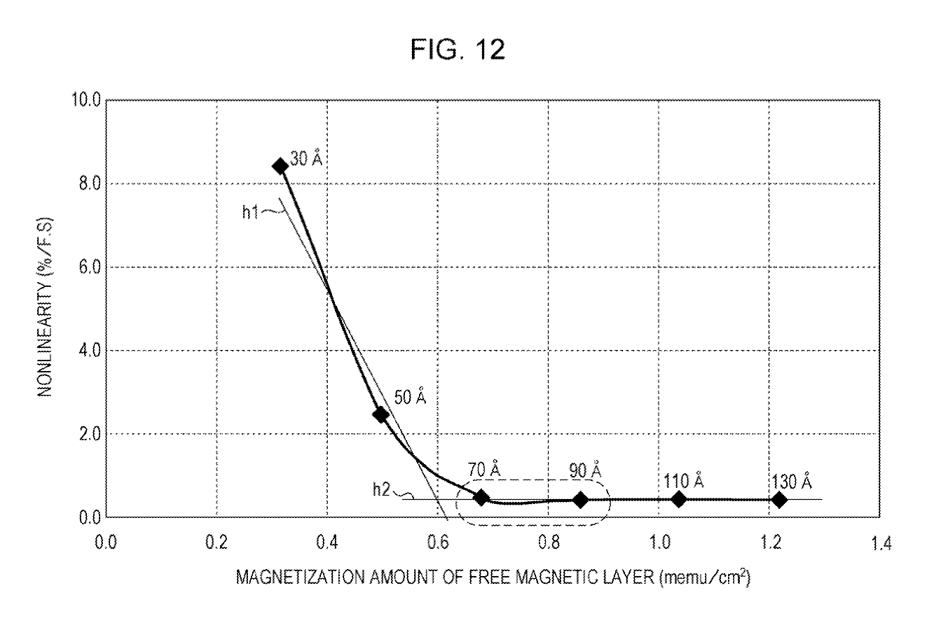

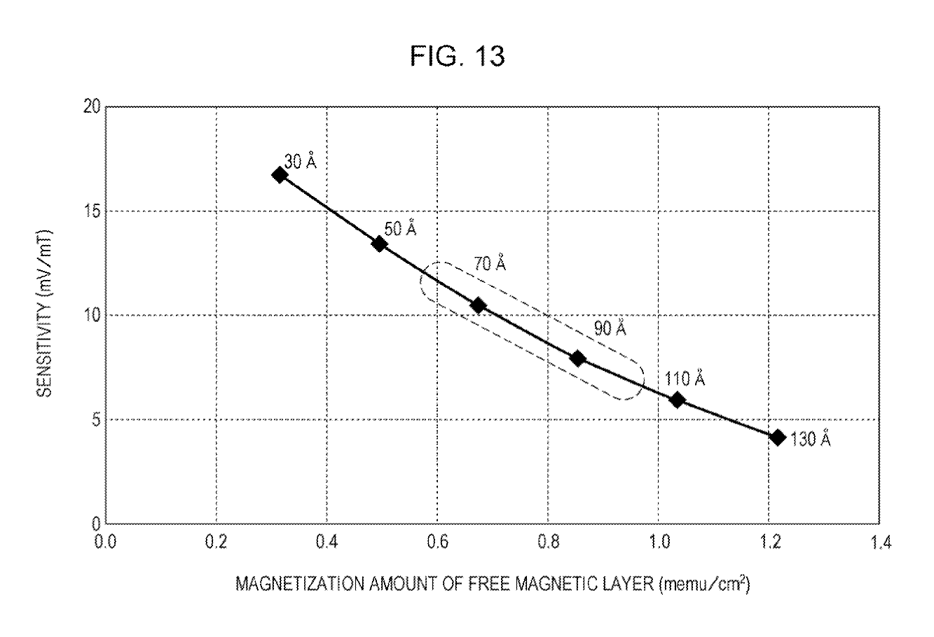

FIG. 11 is a characteristic diagram showing the relationship between magnetic hysteresis and the magnetization amount (Ms•t) of the free magnetic layer in the magnetoresistance effect element. FIG. 12 is a characteristic diagram showing the relationship between nonlinearity and the magnetization amount of the free magnetic layer in the magnetoresistance effect element. FIG. 13 is a characteristic diagram showing the relationship between the sensitivity of the current sensor and the magnetization amount of the free magnetic layer in the magnetoresistance effect element. For measurement of the characteristics in FIGS. 11 to 13, a magnetoresistance effect element is used which is composed of: magnetic detecting portions 32 each having a lamination structure of NiFeCr (seed layer: 4.2 nm)/Fe60Co40 (first ferromagnetic film: 1.9 nm)/Ru (antiparallel coupling film: 0.4 nm)/Co90Fe10 (second ferromagnetic film: 2.4 nm)/Cu (nonmagnetic intermediate layer: 2.2 nm)/Co90Fe10 (free magnetic layer: 1 nm)/Ni81.5Fe18.5 (free magnetic layer: x nm)/Ta (protective layer: 10 nm); and permanent magnet portions 33 each having a lamination structure of Ta (base layer: 1.5 nm)/CrTi (base layer: 3.5 nm)/CoPt (hard bias layer: 60 nm)/Ta (anti-diffusion layer: 5 nm)/Au (electrically conductive layer: 120 nm)/Ta (electrically conductive layer: 5 nm). The magnetization amount of the free magnetic layer is adjusted by changing the thickness of the Ni81.5Fe18.5 layer which is the free magnetic layer. The thicknesses of the Ni81.5Fe18.5 layer corresponding to measurement points are shown in FIGS. 11 to 13. The interval D1 between the adjacent permanent magnet portions 33 is fixed to 60 μm, and the width W1 of each magnetic detecting portion 32 is fixed to 0.8 μm. The method for calculating each characteristic is the same as that in the case of FIGS. 5 to 7.

In the characteristic diagram of FIG. 11, the gradient of the characteristic diagram (the gradient of approximate straight lines g1 and g2) changes at the point where the magnetization amount of the free magnetic layer is 0.6 memu/cm2. From FIG. 11, it appears that the magnetic hysteresis is sufficiently low in the range of 0.6 memu/cm2 or higher in which the approximate straight line g2 and the characteristic curve substantially coincide with each other. Similarly, in the characteristic diagram of FIG. 12, the gradient of the characteristic diagram (the gradient of approximate straight lines h1 and h2) changes at the point where the magnetization amount of the free magnetic layer is 0.6 memu/cm2. From FIG. 12, it appears that the nonlinearity is sufficiently low in the range of 0.6 memu/cm2 or higher in which the approximate straight line h2 and the characteristic curve substantially coincide with each other. This means that the linearity is sufficiently high in the range of 0.6 memu/cm2 or higher. In addition, in the characteristic diagram of FIG. 13, sufficient sensitivity is not obtained when the magnetization amount of the free magnetic layer exceeds 1.0 memu/cm2. In other words, from FIG. 13, it appears that the sensitivity is high in the range of 1.0 memu/cm2 or less.

As described above, when the magnetization amount of the free magnetic layer is set to 0.6 memu/cm2 to 1.0 memu/cm2, a current sensor can be realized in which low magnetic hysteresis, high linearity, and high detection sensitivity are well balanced.

As described above, in the present invention, when the interval between adjacent permanent magnet portions is set to 20 μm to 100 μm in a magnetoresistance effect element used in a current sensor, a current sensor having low magnetic hysteresis, high linearity, and high detection sensitivity can be realized.

It is noted that the present invention is not limited to the embodiment described above and various changes can be made to implement the present invention. For example, each elongated pattern is not limited to the embodiment in which a plurality of permanent magnet portions and a plurality of magnetic detecting portions are spaced apart from each other at a predetermined interval. Each elongated pattern may be composed of a single magnetic detecting portion having a length of 20 μm to 100 μm and permanent magnet portions on both sides thereof. In addition, the materials, the connection relationship between each element, the thickness, the size, the manufacturing method, and the like in the embodiment described above can be changed as appropriate to implement the present invention. Also, appropriate changes can be made without departing from the scope of the present invention, to implement the present invention.

The present invention is applicable, for example, to a current sensor that detects the magnitude of a current for driving a motor of an electric vehicle.

1. A current sensor comprising:
a magnetoresistance effect element in which a plurality of magnetic detecting portions and a plurality of permanent magnet portions are alternately arranged so as to contact each other, each magnetic detecting portion having a ferromagnetic fixed layer whose magnetization direction is substantially fixed and a free magnetic layer whose magnetization direction changes in accordance with an external magnetic field, each permanent magnet portion including a hard bias layer for applying a bias magnetic field to the free magnetic layer, wherein
an interval between the adjacent permanent magnet portions is 20 μm to 100 μm.

2. The current sensor according to claim 1, wherein a width of each magnetic detecting portion is 0.5 μm to 1.5 μm.

3. The current sensor according to claim 1, wherein a magnetization amount of each free magnetic layer is 0.6 memu/cm² to 1.0 memu/cm².

4. The current sensor according to claim 1, wherein each permanent magnet portion further includes an electrically conductive layer electrically connecting the magnetic detecting portions adjacent thereto.

5. The current sensor according to claim 1, wherein the current sensor is a magnetic proportional current sensor comprising a bridge circuit including the magnetoresistance effect element, the bridge circuit being configured to detect a magnetic field and generate a voltage difference substantially proportional to an induced magnetic field.

6. The current sensor according to claim 1, wherein each permanent magnet portion further includes:
an electrically conductive layer formed over the hard bias layer so as to electrically connect two of the magnetic detecting portions adjacent thereto.

7. The current sensor according to claim 1, wherein the alternately-arranged magnetic detecting portions and the permanent magnet portions form a plurality of elongated patterns each extending in a first direction, the plurality of elongated patterns being arranged in a second direction substantially orthogonal to the first direction such that the plurality of elongated patterns are parallel to one another.

8. The current sensor according to claim 1, wherein a length of each of the magnetic detecting portions provides the interval between the adjacent permanent magnet portions.

9. The current sensor according to claim 1, wherein the hard bias layer is configured to apply the magnetic field substantially orthogonal to a sensitivity axis direction of the free magnetic layer.
